(19) United States
(12) Patent Application Publication
(10) Pub. No.: US 2008/0266767 A1
(43) Pub. Date: Oct. 30, 2008

(54) Electronic device having interchangeable display member

(76) Inventors: Kenneth E. Nicholas, Tomball, TX (US); Paul E. Hiles, Tomball, TX (US); Chris Moehring, Tomball, TX (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/796,199

(22) Filed: Apr. 27, 2007

(51) Int. Cl. H05K 5/00

(52) U.S. Cl. 361/681

(57) ABSTRACT

A portable electronic device comprises a housing configured to releasably secure thereto one of a plurality of interchangeable display members, at least two of the plurality of display members comprising different types of display members.

### BACKGROUND

Electronic devices, such as personal digital assistants (PDAs), are utilized in different lighting conditions (e.g., in indoor/dim lighting conditions, outdoor/bright lighting conditions, etc.) due to the portability of the devices. Unfortunately, while a display screen for a particular PDA may be well suited for dim lighting conditions, the same PDA may be virtually unusable in bright lighting conditions.

### BRIEF DESCRIPTION OF THE DRAWINGS

FIG. 1 is a diagram of an electronic device in which an interchangeable display member is employed to advantage; and

FIG. 2 is a diagram illustrating the electronic device of FIG. 1 having a plurality of interchangeable display members detached from the electronic device.

### DETAILED DESCRIPTION OF THE DRAWINGS

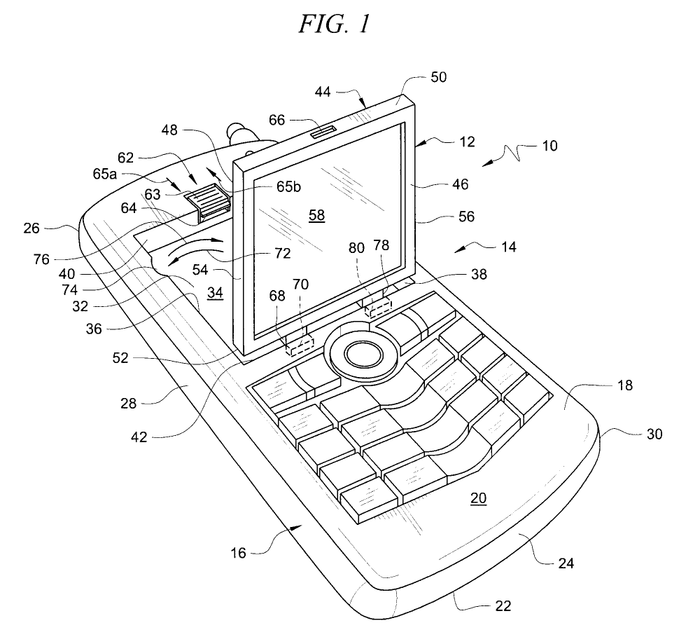

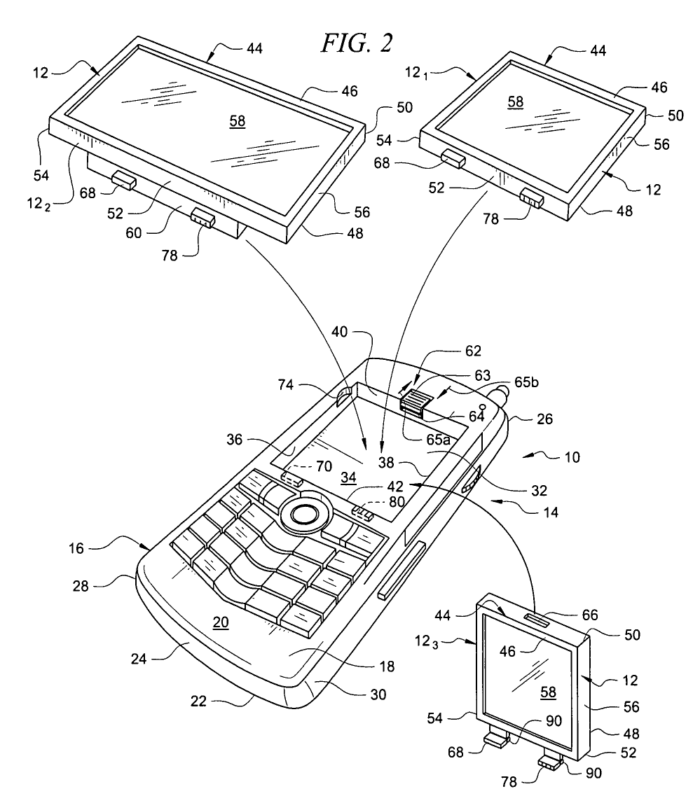

Various embodiments and the advantages thereof are best understood by referring to FIGS. 1 and 2 like numerals being used for like and corresponding parts of the various drawings.

FIG. 1 is a diagram of an electronic device 10 in which an interchangeable display member 12 is employed to advantage, and FIG. 2 is a diagram illustrating electronic device 10 of FIG. 1 having a plurality of interchangeable display members 12 detached from electronic device 10. In the embodiment illustrated in FIGS. 1 and 2, electronic device 10 comprises a smartphone 14; however, it should be understood that electronic device 10 may comprise any type of electronic device such as, but not limited to, a personal digital assistant, a tablet personal computer, a gaming device, an entertainment device, a camera, a personal navigator device, or any handheld other type of portable or non-portable electronic device.

In the embodiment illustrated in FIGS. 1 and 2, display member 12 is removeably coupleable to electronic device 10 and is interchangeable with a different display member 12 to facilitate utilizing electronic device 10 with different types and/or sizes of display members 12. For example, in FIG. 2, display members 12₁, 12₂, and 12₃ are illustrated such that display members 12₁ 12₂ and 12₃ are each removably coupleable to electronic device 10 where display member 12₁ is used for a particular environment (e.g., bright environments such as outdoors during the daytime) and display member 12₂ is used for a different environment (e.g., dim environments such as in a dark room and/or outside during the nighttime). According to some embodiments, display member 12₁ is interchangeable with display member 12₂ to facilitate use of electronic device 10 with a different sized and/or type of display member 12, or to facilitate replacement and/or repair of display member 12₁ and/or 12₂. Further, display member 12₁ is interchangeable with display member 12₃ to facilitate use of display member 12₃ with a privacy filter in an environment where privacy is desired. Thus, it should be understood a variety of different types of display members 12 may be used to accommodate different lighting conditions, different sizes, different levels of security, different types of screens on display member 12, etc.

In the embodiment illustrated in FIGS. 1 and 2, electronic device 10 comprises a housing 16 having a front wall 18 forming a working surface 20, a rear wall 22, a bottom wall 24, a top wall 26 and a pair of sidewalls 28 and 30. In FIGS. 1 and 2, display member 12 is removably coupleable to working surface 20. In the embodiment illustrated in FIGS. 1 and 2, working surface 20 comprises a recessed area 32 formed from bottom wall 34 and sidewalls 36, 38, 40 and 42 to receive display member 12. According to some embodiments, display member 12 is positionable within recessed area 32 such that display member 12 rests flush (flush or substantially flush) with working surface 20. In other embodiments, display member 12 may be positioned in an elevated position relative to working surface 20.

In the embodiment illustrated in FIGS. 1 and 2, display member 12 comprises a housing 44 formed by a front wall 46, a rear wall 48, a top wall 50, a bottom wall 52 and a pair of sidewalls 54 and 56 and configured to support a display screen 58. According to some embodiments, display screen 58 comprises a transmissive type display screen, a reflective type display screen, a privacy type screen, or any other desired type of display screen and/or device (e.g., a microprojector) for displaying output from electronic device 10. Thus, if electronic device 10 is utilized in outdoor/bright environments, a reflective type display screen 58 may be desired and/or if electronic device 10 is utilized in indoor/dark environments, a transmissive display screen 58 may be desired, and/or if display screen 58 is used to display sensitive information/data, a privacy type display screen 58 may be desired. Accordingly, display members 12 are configured having different types of display screens 58 so as to be interchangeable with each other relative to device 10 to meet a particular lighting, environment or other type of condition.

In the embodiment illustrated in FIG. 2, display member 12₂ comprises a display screen 58 having a wide aspect ratio such that housing 44 extends beyond a periphery of electronic device 10 when display member 12₂ is coupled to electronic device 10. In FIG. 2, housing 44 comprises a base member 60 insertible within recessed area 32 to couple display member 12 to electronic device 10 such that display screen 58 is otherwise disposed above working surface 20; however, it should be understood that electronic device 10 may be formed such that recessed area 32 extends across the lateral dimension of electronic device 10 (e.g., with at least a portion of sidewalls 36 and 38 omitted and/or cutaway) to obviate the need for base member 60 and to otherwise enable housing 44, and thus display screen 58, to rest within recessed area 32 and flush (flush or substantially flush) with working surface 20.

In the embodiment illustrated in FIGS. 1 and 2, electronic device 10 comprises a locking mechanism 62 configured to secure display member 12 to electronic device 10. In FIG. 1, locking mechanism 62 comprises an extendable and retractable extension 64 outwardly biased in the direction of arrow 65a to engage a corresponding recess 66 disposed on top wall 50 of display member 12 (see also display member 12₃ for example; although it should be understood that other display members 12 may be similarly configured). In FIG. 2, when coupling display member 12₂ to electronic device 10, base member 60 comprises a recess 66 configured to receive extension 64 to securely fasten display member 12₂ to electronic device 10. Locking mechanism 62 further comprises an extension 68 extending outwardly from bottom wall 52 and insertable within a corresponding recess 70 disposed on electronic device 10. It should be understood that locking mechanism 62 may be otherwise configured (e.g., by providing additional retractable extensions 64 on electronic device 10, by providing a greater or fewer number of extensions 68 disposed on bottom wall 52, by frictional engagement between recessed area 32 and display member 12, by detents, etc.). In operation, when coupling display member 12 to electronic device 10, extension 68 is aligned with and otherwise inserted within corresponding recess 70. Display member 12 is rotated in the direction of arrow 72 (FIG. 1) until extension 64 is inserted within recess 66, thereby securely fastening display member 12 within recessed area 32. For example, as display member 12 is rotated in the direction of arrow 72, top wall 50 of housing 44 contacts extension 64 causing extension 64 to retract in the direction of 65b. As housing 44 is inserted within recessed area 32, recess 66 aligns with extension 64 to enable movement of extension 64 in the direction of arrow 65b to extend inside recess 66. When removing display member 12 from electronic device 10, locking mechanism 62 is actuated by sliding a release button 63 to remove extension 64 from recess 66, thereby enabling display member 12 to be removed from recessed area 32 via a finger insert slot 74 to enable a user to remove display member 12 from recessed area 32 by rotating display member 12 in the direction of arrow 76 (FIG. 1).

Display member 12 also comprises a connector member 78 for engagement with a corresponding connector member 80 disposed within recessed area 32, as illustrated in FIG. 2. Connector members 78 and 80 are configured to facilitate communicative engagement between display member 12 and electronic device 10 while also securing display member 12 in recessed area 32 (by positive engagement between connector members 78 and 80). However, it should be understood that connector members 78 and 80 can be otherwise located (e.g., disposed on extension 68, disposed on any wall 46, 48, 52, 54 and/or 56 of housing 44 or wall 34, 36, 38, 40 and/or 42 of recessed area 32) and/or formed apart from locking mechanism 62.

According to some embodiments, display member 12₃ comprises an extension 68 and connector 78 both comprising a hinge 90 to facilitate variable positioning of display member 12₃ relative to electronic device 10. For example, in the embodiment illustrated in FIG. 2, extension 68 and connector 78 are inserted within corresponding recesses 70 and 80 to securely fasten display member 12₃ to electronic device 10. While secured to electronic device 10, hinges 90 facilitate variable positioning of display member 12₃ relative to electronic device 10 (e.g., positioning of display member 12₃ within recessed area 32 or removed from recessed area 32 and angularly positioned relative to electronic device 10). Furthermore, according to some embodiments, in the event housing 44 is sized smaller than recessed area 32, extension 68 and connector 78 may be manufactured with a longer length to engage recesses 70 and 80, respectively, to facilitate locking of display member 12 to electronic device 10.

Thus, embodiments of electronic device 10 may be manufactured to enable interchangeable display member 12 to facilitate use of electronic device 10 in different lighting conditions, utilizing different sized display screens 12, and/or utilizing different filtered display screens, etc.

What is claimed is:

1. A portable electronic device, comprising:
a housing configured to releasably secure thereto one of a plurality of interchangeable display members, at least two of the plurality of display members comprising different types of display members.

2. The portable electronic device of claim 1, wherein at least two of the plurality of display members comprise a different size of display screen.

3. The portable electronic device of claim 1, wherein at least two of the plurality of display members are configured for correspond to different lighting conditions.

4. The portable electronic device of claim 1, wherein the at least one of the plurality of display members comprises a privacy screen.

5. The portable electronic device of claim 1, further comprising a locking mechanism configured to secure the one display member to the housing.

6. The portable electronic device of claim 1, further comprising a retractable extension configured to secure the one display member to the electronic device.

7. The portable electronic device of claim 1, further comprising a connector member for communicative engagement with a corresponding connector member disposed on each of the plurality of display members.

8. The portable electronic device of claim 1, wherein at least one of the plurality of display members extends beyond a periphery of the housing when attached thereto.

9. A method of manufacturing a portable electronic device, comprising:
providing a housing configured to releasably secure thereto one of a plurality of interchangeable display members, at least two of the plurality of display members comprising different types of display members.

10. The method of claim 9, further comprising providing at least two of the plurality of display members having a different size display screen.

11. The method of claim 9, further comprising providing at least two of the plurality of display members for different lighting conditions.

12. The method of claim 9, further comprising providing at least one of the plurality of display members with a privacy screen.

13. The method of claim 9, further comprising providing a locking mechanism configured to secure the one display member to the housing.

14. The method of claim 9, further comprising providing a retractable extension configured to secure the one display member to the electronic device.

15. The method of claim 9, further comprising providing a connector member for communicative engagement with a corresponding connector member disposed on each of the plurality of display members.

16. The method of claim 9, further comprising providing at least one of the plurality of display members extending beyond a periphery of the housing when attached thereto.

17. A portable electronic device, comprising:
a housing means configured to releasably secure thereto one of a plurality of interchangeable display means, at least two of the plurality of display means comprising different types of display means.

18. The portable electronic device of claim 17, wherein at least two of the plurality of display means comprise a different size of display screen.

19. The portable electronic device of claim 17, wherein at least two of the plurality of display means are configured to different lighting conditions.

20. The portable electronic device of claim 17, wherein at least one of the plurality of display means comprises a privacy screen.
